(19) United States
(12) Patent Application Publication
(10) Pub. No.: US 2024/0322058 A1
(43) Pub. Date: Sep. 26, 2024

(54) SOLAR CELL PANEL AND SOLAR CELL SYSTEM

(71) Applicant: DENSO CORPORATION, Kariya-city (JP)

(72) Inventors: Yoshimasa HIJIKATA, Kariya-city (JP); Yasufumi SUZUKI, Kariya-city (JP)

(21) Appl. No.: 18/734,346

(22) Filed: Jun. 5, 2024

Related U.S. Application Data
(63) Continuation of application No. PCT/JP2022/041642, filed on Nov. 9, 2022.

(30) Foreign Application Priority Data
Dec. 28, 2021 (JP) 2021-214443

(51) Int. Cl. H01L 31/054; B60L 8/00; H01L 31/0224

(52) U.S. Cl. CPC H01L 31/054; B60L 8/003; H01L 31/022475

(57) ABSTRACT

A solar cell panel includes a solar cell layer and a transmission/reflection switching layer. The solar cell layer receives sunlight to generate electricity, and has a light transmissivity. The transmission/reflection switching layer is configured to be switchable between a mirror state that reflects visible light and a transmission state that allows the visible light to pass through. The solar cell panel may be included in a solar cell system for a vehicle together with a detector and a controller that controls the mirror state and the transmission state of the transmission/reflection switching layer based on a detection signal of the detector.

### CROSS REFERENCE TO RELATED APPLICATIONS

The present application is a continuation application of International Patent Application No. PCT/JP2022/041642 filed on Nov. 9, 2022, which designated the U.S. and claims the benefit of priority from Japanese Patent Application No. 2021-214443 filed on Dec. 28, 2021. The entire disclosures of all of the above applications are incorporated herein by reference.

### TECHNICAL FIELD

The present disclosure relates to a solar cell panel and a solar cell system.

### BACKGROUND

For example, a solar cell includes a conversion layer that converts sunlight into electric energy and electrodes provided on both sides of the conversion layer. A transparent conductive layer is used for the electrode on a sunlight transmission side, and a metal plate that reflects light is used for the electrode on an opposite side. By reflecting the light entering the solar cell on the metal plate and guiding it to the conversion layer, the entered light is effectively used and the conversion efficiency of the solar cell is improved. However, since transparency is lost due to the metal plate, it has been difficult to apply the solar cell to a glass part that needs to be transparent in viewing.

### SUMMARY

The present disclosure describes a solar cell panel and a solar cell system. According to an aspect, a solar cell includes a solar cell layer and a transmission/reflection switching layer. The solar cell layer generates electricity by receiving sunlight and has a light transmissivity. The transmission/reflection switching layer that is configured to be switchable between a mirror state that reflects visible light and a transmission state that allows the visible light to pass through.

### BRIEF DESCRIPTION OF THE DRAWINGS

FIG. 1 is a conceptual diagram showing an overall configuration of a solar cell system according to a first embodiment.

FIG. 2 is an explanatory diagram showing a reflection state of sunlight in a solar cell panel according to the first embodiment.

FIG. 3 is an explanatory diagram showing a transmission state of sunlight in the solar cell panel according to the first embodiment.

FIG. 4 is a conceptual diagram showing an overall configuration of a solar cell system according to a second embodiment.

FIG. 5 is a conceptual diagram showing an overall configuration of a solar cell system according to a third embodiment.

FIG. 6 is a conceptual diagram showing an overall configuration of a solar cell system according to a fourth embodiment.

### DETAILED DESCRIPTION

For example, a solar cell having translucency may be applied to a window glass of a house or building.

In such a case, electrodes disposed on both sides of a conversion layer, which converts sunlight into electric energy, need to be formed of transparent conductive layers in order to ensure transparency. In such a configuration, however, it may be difficult to effectively use incident light, resulting in decrease in a conversion efficiency of the solar cell.

The present disclosure provides a solar cell panel and a solar cell system, which are capable of achieving both transparency and high conversion efficiency.

A solar cell panel according to an aspect of the present disclosure includes: a solar cell layer that generates electricity by receiving sunlight and has a light transmissivity; and a transmission/reflection switching layer that is configured to be switchable between a mirror state that reflects visible light and a transmission state that allows the visible light to pass through.

According to such a configuration, since the transmission/reflection switching layer is provided, the transparency can be ensured by switching the transmission/reflection switching layer to the transmission state. Moreover, by switching the transmission/reflection switching layer to the reflection state, the sunlight is reflected to be incident on the solar cell layer, resulting in the improvement of power generation efficiency in the solar cell layer. As a result, it is possible to achieve both the transparency and the high conversion efficiency.

Hereinafter, embodiments for implementing the present disclosure will be described with reference to the drawings. In the respective embodiments, parts corresponding to matters already described in the preceding embodiment(s) are given reference numbers identical to reference numbers of the matters already described, and the same description may not be repeated. In a case where only a part of the configuration is described in each embodiment, the other embodiments described above can be applied to the other part of the configuration. The present disclosure is not limited to combinations of embodiments which combine parts that are explicitly described as being combinable. As long as no problem arises, the various embodiments may be partially combined with each other even if not explicitly described.

### First Embodiment

The following describes a first embodiment of the present disclosure with reference to the drawings. The solar cell system of the present embodiment is mounted on a vehicle and is used as a solar cell system for a vehicle.

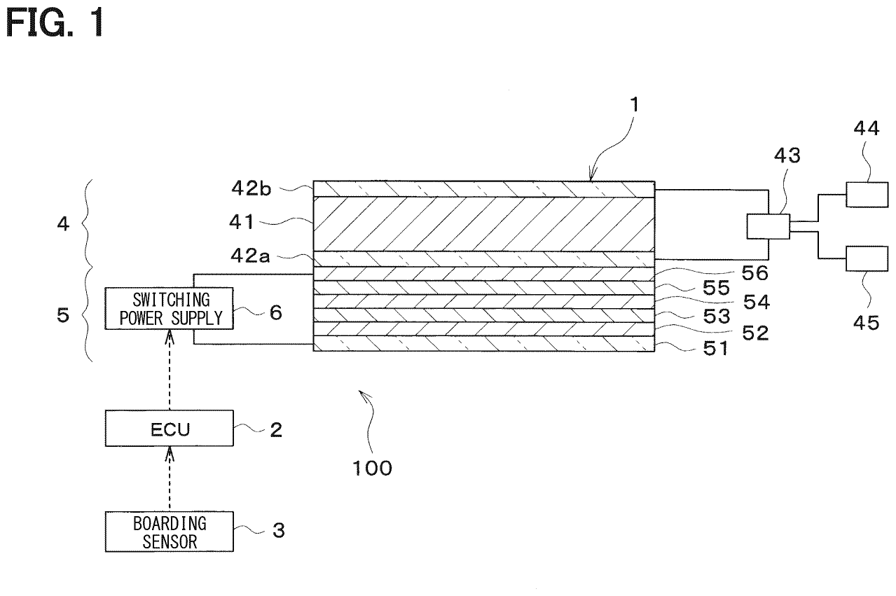

As shown in FIG. 1, the solar cell system 100 of the present embodiment includes a solar cell panel 1, a control device 2, and a boarding sensor 3. The solar cell panel 1 is provided at a window part of a vehicle. Specifically, the solar cell panel 1 is provided on at least one of a windshield, a door glass, a sunroof, or a rear glass of the vehicle. In the present embodiment, the solar cell panel 1 is detachably provided on the windshield of a vehicle.

The solar cell panel 1 includes a solar cell layer 4 and a transmission/reflection switching layer 5. The solar cell panel 1 is configured by a stack of the solar cell layer 4 and the transmission/reflection switching layer 5. The solar cell layer 4 is a solar cell that receives sunlight to generate electricity and has a light transmissivity. The transmission/reflection switching layer 5 is configured to be switchable between a mirror state that reflects visible light and a transmission state that allows the visible light to pass through.

The solar cell layer 4 includes a conversion layer 41 that converts sunlight into electric energy, and transparent electrode films 42a and 42b provided on both sides of the conversion layer 41. The conversion layer 41 is made of a semiconductor material having a light transmissivity. The conversion layer 41 is made of, for example, a silicon-based semiconductor material. Note that in this specification, “having light transmissivity” does not only mean that it is completely transparent, but also means that it has the property of allowing light to pass through. As such, the conversion layer 41 may be semitransparent, for example.

The transparent electrode films 42a and 42b are made of a transparent electrode material such as tin-doped indium oxide (ITO) or fluorine-doped tin oxide (FTO). The transparent electrode films 42a and 42b may be each made of a bendable transparent conductive film. Further, the transparent electrode film may be composed of carbon nanotubes.

Hereinafter, of the transparent electrode films 42a and 42b, the one disposed on a side adjacent to the transmission/reflection switching layer 5 is referred to as the inner transparent electrode film 42a, and the other disposed on a side opposite to the transmission/reflection switching layer 5 is referred to as the outer transparent electrode film 42b.

The outer transparent electrode film 42b is arranged outside the conversion layer 41. The inner transparent electrode film 42a is arranged inside the conversion layer 41.

The inner transparent electrode film 42a and the outer transparent electrode film 42b are electrically connected to a storage battery 44 and a load 45 via a converter 43. The storage battery 44 or the load 45 may be omitted. The load 45 may also be configured to utilize electric energy stored in the storage battery 44.

The converter 43 is a device that has a circuit or element that performs voltage transformation or power conversion such as direct current and alternating current conversion, and is for example, a DC-DC converter, a DC-AC converter, or an AC-AC converter. The converter 43 can have a suitable configuration depending on the voltage to be generated or the configuration of the storage battery 44 or the load 45.

When the solar cell layer 4 included in the solar cell panel 1 receives light, it generates electricity. The electric energy is converted by the converter 43, and the converted electric energy is stored in the storage battery 44 or consumed by the load 45.

The transmission/reflection switching layer 5 is configured as an electrochromic layer. The transmission/reflection switching layer 5 is configured to be electrically switchable between a mirror state and a transmission state. The transmission/reflection switching layer 5 is formed by a stack of a transparent conductive film 51, an ion storage layer 52, a solid electrolyte layer 53, a buffer layer 54, a catalyst layer 55, and a light modulation mirror layer 56.

As the transparent conductive film 51, ITO can be used. For the ion storage layer 52, WO₃ can be used. For the solid electrolyte layer 53, Ta₂O₅ can be used. For the buffer layer 54, Al can be used. For the catalyst layer 55, Pd can be used. For the light modulation mirror layer 56, an electrochromic material such as Mg—Ni alloy can be used. Note that the transparent conductive film 51, the ion storage layer 52, the solid electrolyte layer 53, the buffer layer 54, the catalyst layer 55, and the light modulation mirror layer 56 are not limited to the materials described above, and may be made by using other materials.

The transparent conductive film 51, the ion storage layer 52, the solid electrolyte layer 53, the buffer layer 54, the catalyst layer 55, and the light modulation mirror layer 56 can be each film-formed at room temperature using a magnetron sputtering apparatus. The light modulation mirror layer 56 and the transparent conductive film 51 function as electrodes for supplying the electric power from the switching power supply 6. The control device 2 controls on or off of the switching power supply 6, that is, application or non-application of the voltage to the light modulation mirror layer 56 and the transparent conductive film 51. As the switching power supply 6, a DC power source can be used.

An initial state of the transmission/reflection switching layer 5 is the mirror state. When a voltage of about 5 V is applied, hydrogen ions stored in the ion storage layer 52 move into the light modulation mirror layer 56, and Mg—Ni alloy in a metal state is hydrogenated and becomes a non-metal state, so that the light modulation mirror layer 56 becomes transparent and thus the transmission/reflection switching layer 5 becomes the transmission state. When the polarity is reversed and the voltage of about −5 V is applied, the hydrogen ions return to the ion storage layer 52, and the light modulation mirror layer 56 returns to its original metal state, so that the transmission/reflection switching layer 5 returns to the mirror state. As such, the light modulation mirror layer 56 of the present embodiment corresponds to an example of a switching electrode that is arranged between the solar cell layer 4 and the transmission/reflection switching layer 5, and electrically switches the transmission/reflection switching layer 5 between the mirror state and the transmission state.

The control device 2 includes a well-known microcontroller including a central processing unit (CPU), a read only memory (ROM), a random access memory (RAM) and the like, and peripheral circuits thereof. The control device 2 performs various calculations and processes based on a control program stored in the ROM, and controls the application of voltage to the light modulation mirror layer 56 and the transparent conductive film 51 by the DC power supply 6. The control device 2 of the present embodiment corresponds to an example of a controller.

The boarding sensor 3 is connected to the input side of the control device 2. The boarding sensor 3 is a boarding detection unit that detects getting on and off states of an occupant. A detection signal from the boarding sensor 3 is input to the control device 2. The boarding detection unit of the present embodiment corresponds to an example of a detector.

The boarding sensor 3 detects a getting on motion and a getting off motion of the occupant. For example, a pressure sensor attached to a seat can be used as the boarding sensor 3. In place of the boarding sensor 3, it is also possible to detect the getting on motion and the getting off motion of the occupant based on images captured by an in-vehicle camera (not shown). A sensor for detecting the getting on motion of an occupant and a sensor for detecting the getting off motion of an occupant may be provided separately.

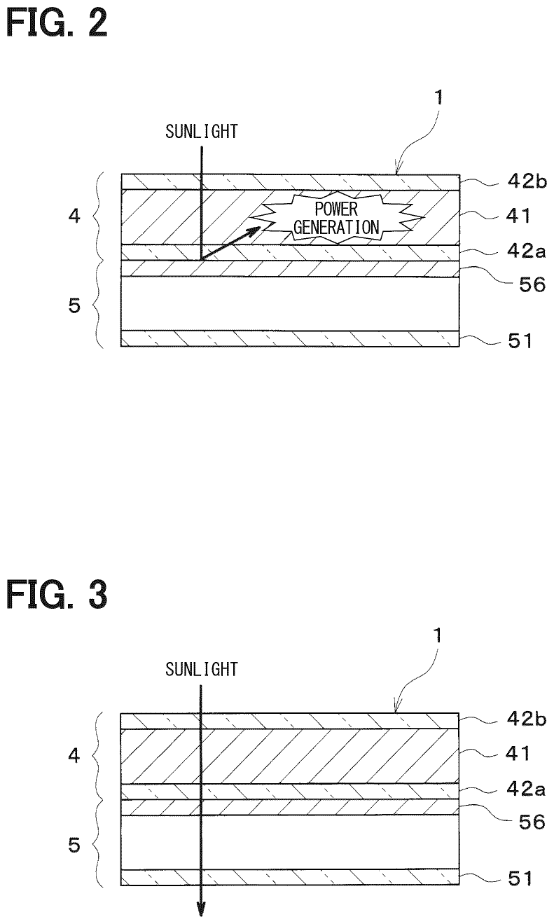

Next, an operation of the present embodiment with the above-described configuration will be described. Note that in FIGS. 2 and 3, illustrations of the ion storage layer 52, the solid electrolyte layer 53, the buffer layer 54, and the catalyst layer 55 are omitted.

In the solar cell system 100 of the present embodiment, when the boarding sensor 3 detects that the occupant is getting off the vehicle, the control device 2 turns off the switching power supply 6 to switch the transmission/reflection switching layer 5 to the mirror state. As a result, as shown in FIG. 2, sunlight that has entered the solar cell panel 1 is reflected by the light modulation mirror layer 56 of the transmission/reflection switching layer 5, and then enters the conversion layer 41 of the solar cell layer 4 again, so that generation of electricity (i.e. energy conversion) is performed.

Further, when the boarding sensor 3 detects that an occupant is getting on the vehicle, the control device 2 turns on the switching power supply 6 to switch the transmission/reflection switching layer 5 to the transmission state. As a result, as shown in FIG. 3, sunlight that has entered the solar cell panel 1 passes through the transmission/reflection switching layer 5.

As described above, the solar cell panel 1 of the present embodiment includes the transmission/reflection switching layer 5 that can be switched between the mirror state and the transmission state. According to this, transparency can be ensured by the transmission/reflection switching layer 5 switched to the transmission state. Also, the transmission/reflection switching layer 5 switched to the reflection state reflects the sunlight to be incident on the solar cell layer 4, thereby improving the power generation efficiency in the solar cell layer 4. As a result, it is possible to achieve both the transparency and the high conversion efficiency.

In addition, in the solar cell system 100 of the present embodiment, when the boarding sensor 3 detects that an occupant is getting off the vehicle, the transmission/reflection switching layer 5 is switched to the mirror state, so that the incident sunlight is reflected by the light modulation mirror layer 56 and enters the solar cell layer 4 again. According to this, when the passenger got off the vehicle and there is no need to ensure the transparency of the window glass, the transmission/reflection switching layer 5 is switched to the mirror state, thereby improving the power generation efficiency in the solar cell layer 4.

Further, in the solar cell system 100 of the present embodiment, when the boarding sensor 3 detects that an occupant is getting on the vehicle, the transmission/reflection switching layer 5 is switched to the transmission state to allow the sunlight to pass through. According to this, when an occupant is on the vehicle and it is necessary to ensure the transparency of the window glass, the transmission/reflection switching layer 5 is switched to the transmission state, thereby to ensure the transparency.

### Second Embodiment

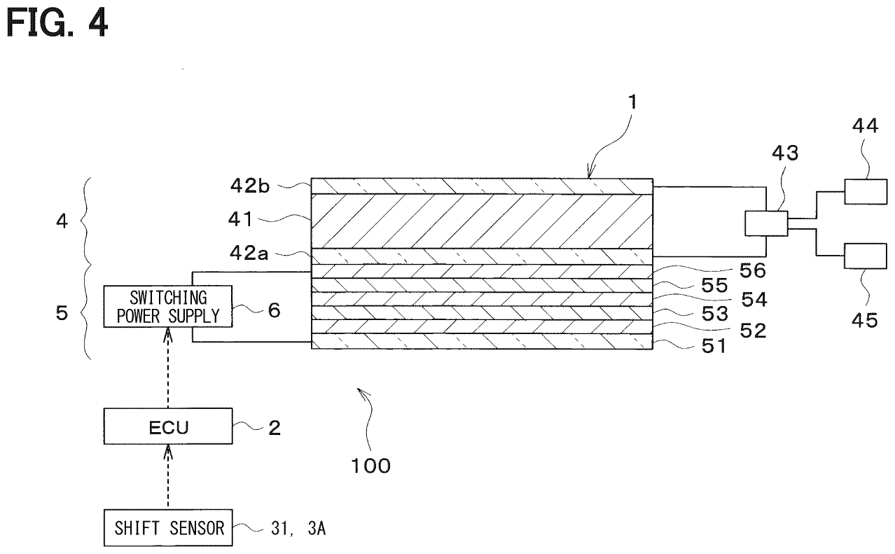

Next, a second embodiment of the present disclosure will be described hereinafter with reference to FIG. 4. As shown in FIG. 4, a solar cell system 100 of the present embodiment includes a stop detection unit 3A that detects a stopped state of a vehicle as the detector. The stop detection unit 3A detects the stopped state, for example, based on a switching state of a shift that changes the direction of travel of the vehicle.

Specifically, the solar cell system 100 of the present embodiment has a shift sensor 31 as the stop detection unit 3A. The shift sensor 31 is connected to the input side of the control device 2. The shift sensor 31 is a sensor that detects the state of the shift, specifically, a gear position. The shift states include drive (D) in which a forward direction is a traveling direction, reverse (R) in which a reverse direction is the traveling direction, parking (P), neutral (N) and the like.

In the solar cell system 100 of the present embodiment, when the stop detection unit 3A detects that the vehicle is in the stopped state, the control device 2 turns off the switching power supply 6 to switch the transmission/reflection switching layer 5 to the mirror state. Specifically, when the shift sensor 31 detects that the shift state is the parking, the control device 2 turns off the switching power supply 6 to switch the transmission/reflection switching layer 5 to the mirror state. As a result, the sunlight that has entered the solar cell panel 1 is reflected by the light modulation mirror layer 56 of the transmission/reflection switching layer 5 to enter the conversion layer 41 of the solar cell layer 4 again, so that the power generation is performed.

Further, when the stop detection unit 3A detects that the vehicle is not stopped, the control device 2 turns on the switching power supply 6 to switch the transmission/reflection switching layer 5 to the transmission state. Specifically, when the shift sensor 31 detects that the shift state is other than the parking, the control device 2 turns on the switching power supply 6 to switch the transmission/reflection switching layer 5 to the transmission state. As a result, the sunlight that has entered the solar cell panel 1 passes through the transmission/reflection switching layer 5.

The other configurations and operations of the solar cell panel 1 and the solar cell system 100 are similar to those in the first embodiment. Therefore, also in the solar cell system 100 of the present embodiment, the similar effects to those in the first embodiment can be achieved. That is, according to the solar cell system 100 of the present embodiment, it is possible to achieve both the transparency and the high conversion efficiency.

In addition, in the solar cell system 100 of the present embodiment, when the stop detection unit 3A detects that the vehicle is in the stopped state, the transmission/reflection switching layer 5 is switched to the mirror state so that the entered sunlight is reflected by the light modulation mirror layer 56 and incident on the solar cell layer 4 again. According to this, when the vehicle is stopped and there is no need to ensure the transparency of the window glass, the transmission/reflection switching layer 5 is switched to the mirror state, so the power generation efficiency in the solar cell layer 4 can be improved.

In the solar cell system 100 of the present embodiment, when the stop detection unit 3A detects that the vehicle is not in the stopped state, the transmission/reflection switching layer 5 is switched to the transmission state to allow the sunlight to pass through. According to this, when the vehicle is not stopped (that is, is in operation) and it is necessary to ensure the transparency of the window glass, the transparent/reflective switching layer 5 is switched to the transparent state and thus the transparency can be ensured.

### Third Embodiment

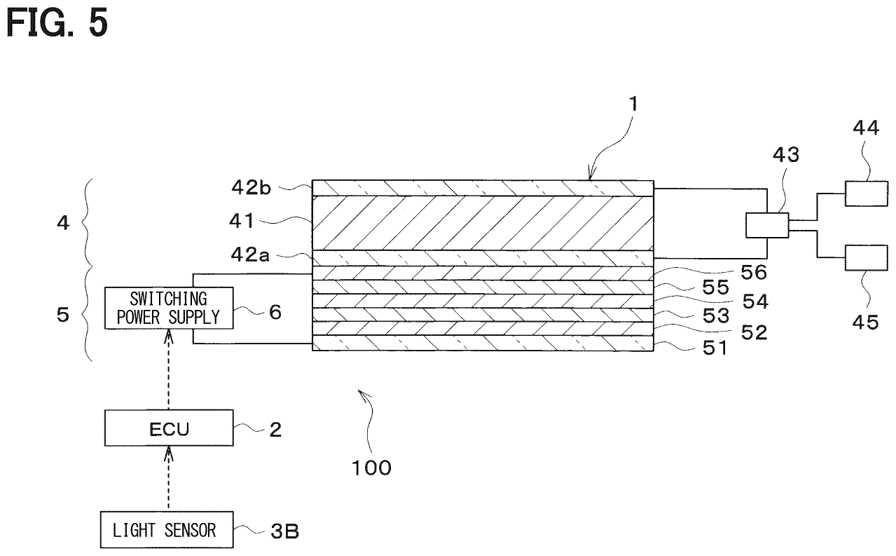

Next, a third embodiment of the present disclosure will be described hereinafter with reference to FIG. 5. As shown in FIG. 5, the solar cell system 100 of the present embodiment includes a light sensor 3B that detects the intensity of light as the detector. The light sensor 3B corresponds to an example of a light detection unit.

When the intensity of the light detected by the light sensor 3B is equal to or higher than a predetermined reference intensity, the control device 2 turns off the switching power supply 6 to switch the transmission/reflection switching layer 5 to the mirror state. As a result, sunlight that has entered the solar cell panel 1 is reflected by the light modulation mirror layer 56 of the transmission/reflection switching layer 5 and incident on the conversion layer 41 of the solar cell layer 4 again to generate electric power.

Further, when the intensity of the light detected by the light sensor 3B is lower than the reference intensity, the control device 2 turns on the switching power supply 6 to switch the transmission/reflection switching layer 5 to the transmission state. As a result, the sunlight that has entered the solar cell panel 1 passes through the transmission/reflection switching layer 5.

The other configurations and operations of the solar cell panel 1 and the solar cell system 100 are similar to those in the first embodiment. Therefore, also in the solar cell system 100 of the present embodiment, the similar effects to those in the first embodiment can be achieved. That is, according to the solar cell system 100 of the present embodiment, it is possible to achieve both the transparency and the high conversion efficiency.

In addition, in the solar cell system 100 of the present embodiment, when the intensity of light detected by the light sensor 3B is equal to or higher than the reference intensity, the transmission/reflection switching layer 5 is switched to the mirror state so that the entered sunlight is reflected by the light modulation mirror layer 56 and is incident on the solar cell layer 4 again. According to this, when the intensity of light entering the solar cell panel 1 is strong, the power generation efficiency in the solar cell layer 4 can be improved by switching the transmission/reflection switching layer 5 to the mirror state.

In the solar cell system 100 of the present embodiment, when the intensity of light detected by the light sensor 3B is lower than the reference intensity, the transmission/reflection switching layer 5 is switched to the transmission state to allow the sunlight to pass through. According to this, when the intensity of light entering the solar cell panel 1 is weak, the transparency can be ensured by switching the transmission/reflection switching layer 5 to the transmission state.

### Fourth Embodiment

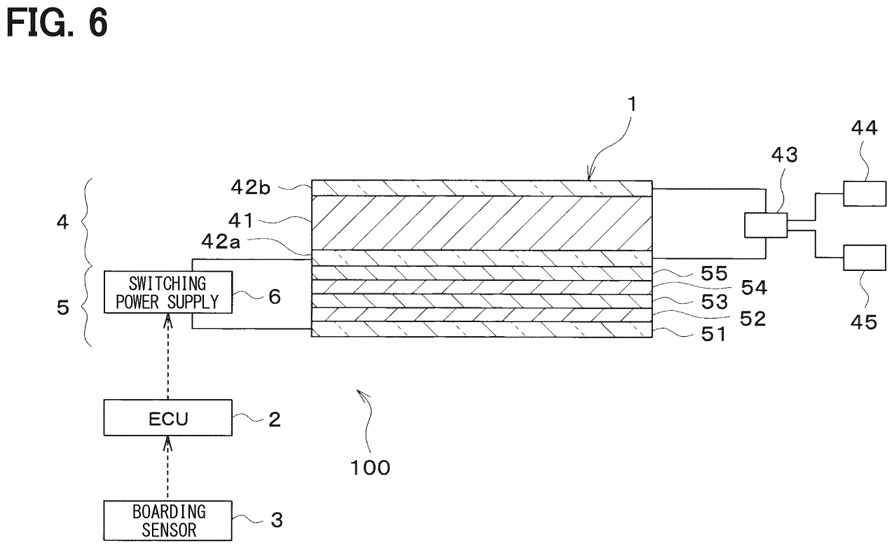

Next, a fourth embodiment of the present disclosure will be described hereinafter with reference to FIG. 6. As shown in FIG. 6, in a solar cell system 100 of the present embodiment, the light modulation mirror layer 56 of the transmission/reflection switching layer 5 is eliminated, as compared to the first embodiment. Further, the inner transparent electrode film 42a is made of an Mg—Ni alloy or the like as an electrochromic material. The inner transparent electrode film 42a is electrically connected to the switching power supply 6.

Therefore, the inner transparent electrode film 42a functions as the light modulation mirror layer 56 of the transmission/reflection switching layer 5. That is, the inner transparent electrode film 42a has both functions as the electrode of the solar cell layer 4 and as the light modulation mirror layer 56 of the transmission/reflection switching layer 5. As a result, there is no need to separately provide the light modulation mirror layer 56 on the transmission/reflection switching layer 5, so that the cost of the solar cell panel 1 can be reduced.

The present disclosure is not limited to the embodiments described hereinabove, and various modifications can be made as follows within a range not departing from the spirit of the present disclosure.

(1) In the embodiment(s) described above, an example has been described in which the transmission/reflection switching layer 5 is configured as the electrochromic layer and is configured to be electrically switchable between the mirror state and the transmission state. However, the transmission/reflection switching layer 5 is not limited to such configurations. For example, the transmission/reflection switching layer 5 may be configured to be mechanically and physically switchable between the mirror state and the transmission state. Specifically, a reflection plate, a roll curtain, or the like may be employed as the transmission/reflection switching layer 5, and the mirror state and the transmission state may be switched electrically or manually.

(2) In the embodiment(s) described above, an example has been described in which the initial state of the transmission/reflection switching layer 5 is the mirror state and is switched to the transmission state in accordance with the voltage application. However, the transmission/reflection switching layer 5 is not limited to such a configuration. For example, the initial state of the transmission/reflection switching layer 5 may be set to the transmission state, and the transmission/reflection switching layer 5 may be switched to the mirror state in accordance with the voltage application. In this case, safety of the vehicle can be improved.

(3) In the embodiment(s) described above, an example has been described in which the solar cell panel 1 of the present disclosure is applied to a window of a vehicle. However, the application of the solar cell panel 1 is not limited to such an example. The solar cell panel 1 of the present disclosure may be applied to glass windows of houses, buildings, or the like.

(4) In the embodiment(s) described above, an example has been described in which the shift sensor 3A is employed as the stop detection unit. However, the stop detection unit is not limited to such an example. For example, a vehicle speed sensor that detects the speed of the vehicle (i.e., vehicle speed) may be employed as the stop detection unit. For example, the vehicle speed sensor outputs a pulse signal to the control device 2 according to the rotation speed of the axle of the vehicle. The control device 2 may determine that the vehicle is in a stopped state when the vehicle speed sensor detects that the vehicle speed is zero.

Although the present disclosure has been described in accordance with the embodiments, it is understood that the present disclosure is not limited to the above embodiments or structures thereof. The present disclosure encompasses various modifications and variations within the scope of equivalents. In addition, while the various elements are shown in various combinations and configurations, which are exemplary, other combinations and configurations, including more, less or only a single element, are also within the spirit and scope of the present disclosure.

What is claimed is:

1. A solar cell panel comprising:
a solar cell layer that receives sunlight to generate electricity and has a light transmissivity; and
a transmission/reflection switching layer that is switchable between a mirror state that reflects a visible light and a transmission state that allows the visible light to pass through.

2. The solar cell panel according to claim 1, wherein
the solar cell layer includes:
a conversion layer that converts the sunlight into electric energy and has the light transmissivity; and
a transparent electrode film provided on both sides of the conversion layer.

3. The solar cell panel according to claim 2, comprising:
a switching electrode disposed between the solar cell layer and the transmission/reflection switching layer to electrically switch the mirror state and the transmission state of the transmission/reflection switching layer.

4. The solar cell panel according to claim 2, wherein
the transparent electrode film includes an inner transparent electrode film disposed adjacent to the transmission/reflection switching layer and an outer transparent electrode film disposed further from the transmission/reflection switching layer than the inner transparent electrode film, and
the inner transparent electrode film switches the mirror state and the transmission state of the transmission/reflection switching layer.

5. The solar cell panel according to claim 2, wherein
the transparent electrode film is a bendable transparent conductive film.

6. The solar cell panel according to claim 2, wherein
the transparent conductive film is made of carbon nanotubes.

7. The solar cell panel according to claim 1, wherein
the transmission/reflection switching layer is provided by an electrochromic layer.

8. A solar cell system for a vehicle, comprising:
the solar cell panel according to claim 1, which is provided at a window part of a vehicle,
a detector that detects at least one of a getting on or off state of an occupant, a stopped state of the vehicle, or an intensity of light; and
a controller that switches, based on a detection signal of the detector, the mirror state and the transmission state of the transmission/reflection switching layer.

9. The solar cell system for a vehicle, according to claim 8, wherein
the detector is a boarding detection unit that detects the getting on or off state of the occupant relative to the vehicle,
in response to the boarding detection unit detecting that the occupant is getting off the vehicle, the controller causes the transmission/reflection switching layer to switched to the mirror state, and
in response to the boarding detection unit detecting that the occupant is getting on the vehicle, the controller causes the transmission/reflection switching layer to be switched to the transmission state.

10. The solar cell system for a vehicle, according to claim 8, wherein
the detector is a stop detection unit that detects a stopped state of the vehicle, and
in response to the stop detection unit detecting that the vehicle is stopped, the controller causes the transmission/reflection switching layer to be switched to the mirror state, and
in response to the stop detection unit detecting that the vehicle is not stopped, the controller causes the transmission/reflection switching layer to be switched to the transmission state.

11. The solar cell system for a vehicle, according to claim 8, wherein
the detector is a light detection unit that detects an intensity of light, and
in response to the intensity of the light detected by the light detection unit being equal to or higher than a predetermined reference intensity, the controller causes the transmission/reflection switching layer to be switched to the mirror state, and
in response to the intensity of the light detected by the light detection unit being lower than the reference intensity, the controller causes the transmission/reflection switching layer to be switched to the transmission state.

12. The solar cell system for a vehicle, according to claim 8, wherein
the solar cell panel is configured to be provided on at least one of a windshield, a door glass, a sunroof, or a rear glass of the vehicle.

13. The solar cell system for a vehicle, according to claim 8, wherein
the solar cell panel is detachably provided on the windshield of the vehicle.

14. A solar cell system for a vehicle, comprising:
the solar cell panel according to claim 1, wherein the solar cell panel is configured to be provided on at least one of a windshield, a door glass, a sunroof, or a rear glass of the vehicle.

15. The solar cell system for a vehicle, according to claim 14, wherein
the solar cell panel is detachably provided on the windshield of the vehicle.
